(19) United States
(12) Patent Application Publication
(10) Pub. No.: US 2016/0300980 A1
(43) Pub. Date: Oct. 13, 2016

(54) Substrates Including Gallium Nitride Layers and a Method of Producing the Same

(71) Applicant: NGK INSULATORS, LTD., Aichi-prefecture (JP)

(72) Inventors: Shuhei Higashihara, Nagoya-city (JP); Makoto Iwai, Kasugai-city (JP); Katsuhiro Imai, Nagoya-city (JP)

(73) Assignee: NGK INSULATORS, LTD., Aichi-prefecture (JP)

(21) Appl. No.: 15/190,672

(22) Filed: Jun. 23, 2016

Related U.S. Application Data
(62) Division of application No. 14/754,817, filed on Jun. 30, 2015.
Application No. 14/754,817 is a continuation of application No. PCT/JP2014/082993, filed on Dec. 12, 2014.

(30) Foreign Application Priority Data
Dec. 20, 2013 (JP) 2013-263397

(51) Int. Cl. H01L 33/00; H01L 33/32

(52) U.S. Cl. CPC H01L 33/0095; H01L 33/32

(57) ABSTRACT

In a substrate having a gallium nitride layer, surface damage after surface treatment of the gallium nitride layer is reduced and quality of a functional device formed thereon is improved. A substrate 4 having at least a gallium nitride layer 4 is provided. A plasma etching system equipped with an inductively coupled plasma generating system is used and a fluorine-based gas is introduced at a standardized direct current bias potential of −10V/cm² or higher to subject a surface 3a of the gallium nitride layer to dry etching treatment.

This application is a Divisional of, and claims priority under 35 U.S.C. §120 to, U.S. patent application Ser. No. 14/754,817, filed Jun. 30, 2015, which was a Continuation of, and claimed priority under 35 U.S.C. §120 to PCT Patent Application No. PCT/JP2014/082993, filed Dec. 12, 2014, and which claimed priority therethrough under 35 U.S.C. §119 to Japanese Patent Application No. 2013-263397, filed Dec. 20, 2013, the entireties of which are incorporated by reference herein.

### TECHNICAL FIELD

The present invention relates to a substrate including a gallium nitride layer and a method of producing the same.

### RELATED ART STATEMENT

Various kinds of light sources have been converted to white LED's. Low-luminance LED's for back lights and electric light bulbs have already become popular and, recently, application of high-luminance LED's to projectors and head lights have been intensively studied. According to recent main-stream white LED's, a light emitting layer of a nitride of a group 13 element is formed on an underlying substrate of sapphire by MOCVD method.

As an underlying substrate for producing a high-luminance LED, it has been expected a GaN self-supporting substrate and a GaN thick film template with improvement of performance expected than sapphire, and its study and development are intensely carried out.

The GaN thick film template includes an underlying substrate such as sapphire or the like and a GaN film having a thickness of 10 μm or larger formed thereon, and can be produced at a cost lower than that of the GaN self-supporting substrate. The inventors developed a GaN thick film template having performances close to those of the GaN self-supporting substrate, by using liquid phase process. As the thickness of the GaN thin film on sapphire by MOCVD method as described above is usually several microns, the one having the thickness as described above is called a thick film.

As an LED is produced on the GaN thick film template, it is expected to realize performances superior than those in the case that it is produced on sapphire, at a cost lower than that in the case it is produced on the GaN self-supporting substrate.

The GaN substrate can be obtained by producing a GaN crystal by HVPE method, flux method or the like and by subjecting it to polishing. For producing a high-luminance LED on GaN crystal, it is demanded that surface state of the GaN crystal is good. That is, the state preferably means that its flatness is of nanometer order without scratches and damages (processing deterioration layer) generated by processing.

It is known several methods for surface finishing of GaN crystal. It includes lapping as mechanical polishing using diamond abrasives, CMP finishing applying both of chemical reaction and mechanical polishing using acidic or alkaline slurry containing abrasives such as colloidal silica, and dry etching finishing by reactive ion etching or the like. Among them, CMP finishing is most popular.

The merit of the lapping is its large processing rate, enabling the completion of the finishing in a short time period. On the other hand, however, as scratches tend to occur on the surface and processing deterioration layer is present on the surface, there is a problem that the quality of a light emitting layer formed on the substrate tends to be deteriorated.

The merits of the CMP finishing is that the processing deterioration layer is not present on the surface and the scratches do not tend to occur. However, as the processing rate is very low, the processing takes a long time and its productivity is low. Further, after a long time CMP processing, considerable influences of the chemical reaction are left so that micro pits tend to be generated on the surface.

Although the dry etching finishing has defects that it is difficult to obtain a smooth surface and contamination tends to occur, it has merits that the processing rate is relatively large and the processing deterioration layer can be prevented at practical level in the case that the control of plasma can be appropriately performed.

As to the dry etching of GaN crystal, the following references are known.

For example, patent document 1 discloses a method using CF₄ gas.

Further, patent document 2 discloses a method using a silicon-containing gas.

Further, patent document 3 discloses a method of etching a GaN series compound semiconductor after polishing.

Further, patent document 4 discloses a method of subjecting a GaN crystal substrate after CMP to dry etching.

Further, patent document 5 discloses a method of removing a processing deterioration layer by dry etching.

Further, patent document 6 describes impurities accompanied with surface treatment.

### PRIOR TECHNICAL DOCUMENTS

### Patent Documents

(Patent document 1) Japanese patent No. 2,613,414B
(Patent document 2) Japanese patent No. 2,599,250B
(Patent document 3) Japanese patent publication No. 2001-322,899A
(Patent document 4) Japanese patent No. 3,546,023B
(Patent document 5) Japanese patent No. 4,232,605B
(Patent document 6) Japanese patent publication No. 2009-200,523A

### SUMMARY OF THE INVENTION

In the case that a GaN substrate is subjected to dry etching, a chlorine-based gas is conventionally used. This is because the processing rate is generally larger by using the chlorine-based gas. For example, according to the patent documents 4 and 6, the chlorine-based gas is preferably used for the dry etching of a GaN-based compound semiconductor.

Although a fluorine-based gas is often used in etching of an Si substrate, it is rarely used for GaN series material.

However, in the case that a GaN substrate is subjected to dry etching using the chlorine-based gas, it is proved that processing damages, which are not negligible, are left even if various kinds of conditions are studied.

Thus, the inventors paid the attention to a fluorine-based gas and tried to subject the surface of the GaN substrate to dry etching. Here, according to the patent document 1, the dry etching of the surface of the GaN substrate was performed using CF₄ gas. As the surface of the GaN substrate after the surface processing was observed by photoluminescence, luminescence peaks having a high intensity ratio was observed. However, after a light emitting layer is formed on the substrate, it was proved that leak current becomes considerable during driving at a low voltage and LED performances were not good.

An object of the present invention is, in a substrate having at least a surface gallium nitride layer, to reduce surface damage after surface treatment of the gallium nitride layer.

The present invention provides a substrate having at least a surface gallium nitride layer, wherein a surface of the gallium nitride layer is subjected to a dry etching treatment by using a plasma etching system equipped with a inductively coupled plasma generating system and by introducing a fluorine-based gas.

The present invention further provides a method of producing a substrate having at least a surface gallium nitride layer, the method comprising:

using a plasma etching system equipped with an inductively coupled plasma generating system and introducing a fluorine-based gas to subject a surface of the gallium nitride layer to a dry etching treatment.

As the inventors measured the surface of the GaN substrate after the etching treatment using CF₄ gas, according to the descriptions of the patent document 1, by photo luminescence, it was considered that the intensity ratio of the peak was large and its surface state was good. Here, a substrate having at least a surface gallium nitride layer is called “GaN substrate”. However, as a light emitting layer was formed thereon, it was proved that a leak current was large at a low driving voltage.

Thus, the inventors observed the surface of the GaN substrate after the etching treatment by CF₄ gas by cathode luminescence (it is called CL below). Thus, the peak intensity ratio of the CL spectra before and after the dry etching treatment in a bright portion was proved to be still low. That is, although an image can be distinguishable than that before the dry etching, the intensity ratio of luminescence spectra was still low, providing a dark image, so that dark spots could not be clearly observed.

The reasons can be speculated as follows. That is, the presence or absence of processing damages on the surface of the GaN substrate should be observed by either of photo luminescence (it is called PL below) and CL. However, the sensitivity to the processing damage of CL is higher than that of PL. As laser light is made incident into the substrate and its reflection is observed according to PL, the resolution in the depth is of micron order in which the laser light penetrates. On the other hand, according to CL, electron beam is made incident and its luminescence is observed. As the electron beam is rapidly absorbed at the upper most surface region, it is possible to obtain information at the uppermost surface region.

As a result, by performing the dry etching treatment using the chlorine-based gas, it is proved that the CL image is not bright even when the processing amount is increased.

Further, in the case that the surface of the GaN substrate after the etching treatment using CF₄ gas was observed by PL, it is considered that micro damages could not be detected.

Based on the discovery, the inventors further studied the method of patent document 1. As a result, the attention was paid to the point that plasma of CF₄ gas was generated by parallel plate type system in patent document 1, which was changed to plasma generated by an inductively coupled system. As a result, it was found that an image of high contrast of intensity ratio could be obtained by PL as well as CL and that dark spots could be clearly observed. This is due to the fact that the surface state of the GaN substrate was considerably improved.

Although the cause is not clear, it is considered that GaF₃ with low volatility would be generated by reaction to play a role of protecting the surface, according to the inventive substrate.

### BRIEF DESCRIPTION OF THE DRAWINGS

FIG. 1(a) is a view schematically showing a gallium nitride layer 2 formed on a seed crystal substrate 1, FIG. 1(b) is a view schematically showing a GaN substrate, and FIG. 1(c) is a view schematically showing a functional device 15 including a GaN substrate 4 and a functional device structure 5 formed thereon.

### EMBODIMENTS FOR CARRYING OUT THE INVENTION

(Applications)

The present invention may be used in technical fields requiring high quality, such as a blue LED with improved color rendering index and expected as a post luminescent lamp, a blue-violet laser for high-speed and high-density optical memory, a power device for an inverter for a hybrid car or the like.

(Substrate Including at Least a Surface Gallium Nitride Layer)

The substrate of the invention is one having at least a gallium nitride layer at its surface. It is called “GaN substrate” below. The inventive substrate may be a self-supporting substrate made of gallium nitride only. Alternatively, the inventive GaN substrate may be a substrate including a separate supporting body and a gallium nitride layer formed thereon. Further, the GaN substrate may include another layer such as an underlying layer, an intermediate layer or a buffer layer, in addition to the gallium nitride layer and supporting body.

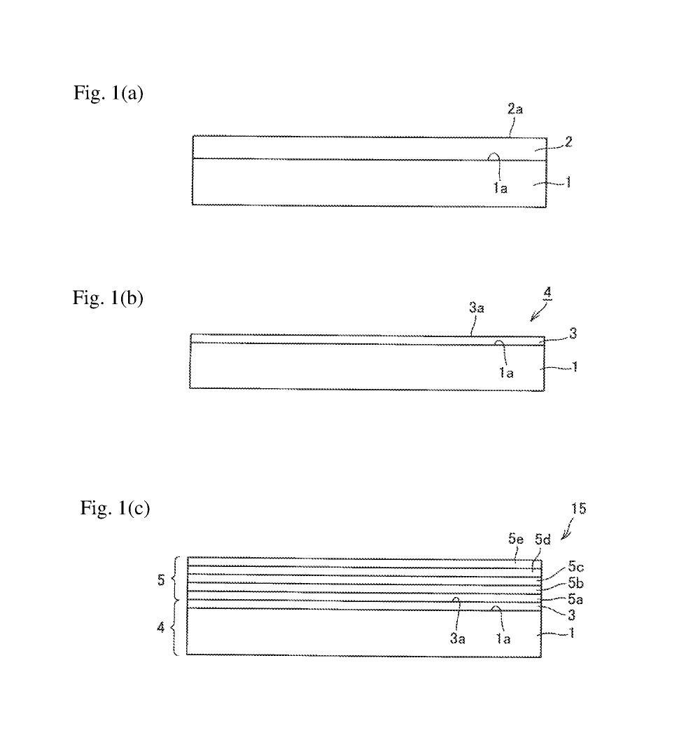

According to a preferred embodiment, as shown in FIG. 1(a), a gallium nitride layer 2 is formed on a surface 1a of a seed crystal substrate 1. Then, preferably, a surface 2a of the gallium nitride layer 2 is subjected to polishing to make a gallium nitride layer 3 thinner, as shown in FIG. 1(b), to obtain a GaN substrate 4. 3a represents a surface after the polishing.

A functional layer 5 is formed, by vapor phase process, on the surface 3a of the thus obtained GaN substrate 4 to obtain a functional device 15 (FIG. 1(c)). Besides, 5a, 5b, 5c, 5d and 5e represent appropriate epitaxial layers grown on the surface 3a.

The whole of the seed crystal substrate 1 may be composed of a self-supporting substrate of GaN. Alternatively, the seed crystal substrate 1 may be composed of a supporting body and a seed crystal film formed on the supporting body. Further, preferably, the surface 2a of the gallium nitride layer 2 is subjected to polishing to make the gallium nitride layer thinner to obtain the GaN substrate.

According to the present invention, the surface of the GaN substrate is subjected to the dry etching. According to a preferred embodiment, the surface was mechanically polished and then subjected to dry etching without performing chemical mechanical polishing.

(Seed Crystal)

According to a preferred embodiment, the seed crystal is composed of gallium nitride crystal. The seed crystal may form the self-supporting substrate (supporting body) or may be the seed crystal film formed on the separate supporting body. The seed crystal film may be composed of a single layer or may include the buffer layer on the side of the supporting body.

The method of forming the seed crystal film may preferably be vapor phase process, and metal organic chemical vapor deposition (MOCVD) method, hydride vapor phase epitaxy method, pulse-excited deposition (PXD) method, MBE method and sublimation method are exemplified. Metal organic chemical vapor deposition is most preferred. Further, the growth temperature may preferably be 950 to 1200° C.

In the case that the seed crystal film is formed on the supporting body, although the material forming the supporting body is not limited, it includes sapphire, AlN template, GaN template, self-supporting GaN substrate, silicon single crystal, SiC single crystal, MgO single crystal, spinel (MgAl₂O₄), LiAlO₂, LiGaO₂, and perovskite composite oxide such as LaAlO₃, LaGaO₃ or NdGaO₃ and SCAM (ScAlMgO₄). A cubic perovskite composite oxide represented by the composition formula [A_{1-y}(Sr₁₋ₓBaₓ)_{y}] [(Al_{1-z}Ga_{z})₁₋ᵤDᵤ]O₃ (wherein A is a rare earth element; D is one or more element selected from the group consisting of niobium and tantalum; y=0.3 to 0.98; x=0 to 1; z=0 to 1; u=0.15 to 0.49; and x+z=0.1 to 2) is also usable

The direction of growth of the gallium nitride layer may be a direction normal to c-plane of the wurtzite structure or a direction normal to each of the a-plane and m-plane.

The dislocation density at the surface of the seed crystal is preferably lower, on the viewpoint of reducing the dislocation density of the gallium nitride layer provided on the seed crystal. On the viewpoint, the dislocation density of the seed crystal layer may preferably be 7×10⁸ cm⁻² or lower and more preferably be 5×10⁸ cm⁻² or lower. Further, as the dislocation density of the seed crystal may preferably be lower on the viewpoint of the quality, the lower limit is not particularly provided, but it may generally be 5×10⁷ cm⁻² or higher in many cases.

(Gallium Nitride Layer)

Although the method of producing the gallium nitride layer is not particularly limited, it includes vapor phase process such as metal organic chemical vapor deposition (MOCVD) method, hydride vapor phase epitaxy (HVPE) method, pulse-excited deposition (PXD) method, MBE method and sublimation method, and liquid phase process such as flux method.

According to a preferred embodiment, the gallium nitride layer is grown by flux method. In this case, the kind of the flux is not particularly limited, as far as it is possible to grow gallium nitride crystal. According to a preferred embodiment, it is used a flux containing at least one of an alkali metal and alkaline earth metal, and flux containing sodium metal is particularly preferred.

A gallium raw material is mixed to the flux and used. As the gallium raw material, gallium single metal, a gallium alloy and a gallium compound are applicable, and gallium single metal is suitably used from the viewpoint of handling.

The growth temperature of the gallium nitride crystal in the flux method and the holding time during the growth are not particularly limited, and they are appropriately changed in accordance with a composition of the flux. As an example, when the gallium nitride crystal is grown using a flux containing sodium or lithium, the growth temperature may be preferably set at 800° C. to 950° C., and more preferably set at 800 to 900° C.

According to flux method, a single crystal is grown in an atmosphere containing nitrogen-containing gas. For this gas, nitrogen gas may be preferably used, and ammonia may be used. The total pressure of the atmosphere is not particularly limited; but it may be preferably set at 3 MPa or more, and further preferably 4 MPa or more, from the standpoint of prevention against the evaporation of the flux. However, as the pressure is high, an apparatus becomes large. Therefore, the total pressure of the atmosphere may be preferably set at 7 MPa or lower, and further preferably 5 MPa or lower. Any other gas except the nitrogen-containing gas in the atmosphere is not limited; but an inert gas may be preferably used, and argon, helium, or neon may be particularly preferred.

(Cathode Luminescence)

Cathode luminescence is to evaluate microscopic deviations on the surface of the GaN substrate. According to the present invention, the cathode luminescence of a wavelength corresponding to band gap of gallium nitride is measured at the surface of the GaN substrate.

In the case that mapping is performed, distribution of cathode luminescence spectrum is measured at each point and luminous intensities at a specific wavelength region are compared to perform the mapping. By limiting the wavelength region, it becomes possible to draw cathode luminescence peak spectrum due to the band gap only. Based on the peaks of the cathode luminescence, an average gradation (Xave) as an average of the intensities and a peak gradation (Xpeak) as the maximum value of the intensities can be calculated.

According to a preferred embodiment, in the image of the cathode luminescence mapping, the dark spots can be detected. According to the cathode luminescence, in the case that the mapping is performed based on the luminescence due to band edge, the luminescence due to the band edge cannot be observed in the dislocation regions and its luminance intensity becomes considerably lower than that of the surroundings, which is observed as the dark spots. It is preferred to elevate an acceleration voltage to 10 kV or larger for clearly distinguishing the light emitting regions and non-light emitting regions. By counting the number of the dark spots in the non-light emitting region by mapping in a specific visual field range, for example visual field of 100 μm, the density of the dark spots can be evaluated.

(Processing and Shape of GaN Substrate)

According to a preferred embodiment, the GaN substrate has a shape of a circular plate, and it may have another shape such as a rectangular plate. Further, according to a preferred embodiment, the dimension of the GaN substrate is of a diameter φ of 25 mm or larger. It is thereby possible to provide the GaN substrate which is suitable for the mass production of functional devices and easy to handle.

It will be described as to the case that the surface of the GaN substrate is subjected to grinding and polishing.

Grinding is that an object is contacted with fixed abrasives obtained by fixing the abrasives by a bond and rotating at a high rotation rate to grind a surface of the object. By such grinding, a roughed surface is formed. In the case that a bottom face of a gallium nitride substrate is ground, it is preferably used the fixed abrasives containing the abrasives, composed of SiC. Al₂O₃, diamond, CBN (cubic boron nitride, same applies below) or the like having a high hardness and having a grain size of about 10 μm to 100 μm.

Further, lapping is that a surface plate and an object are contacted while they are rotated with respect to each other through free abrasives (it means abrasives which are not fixed, same applies below), or fixed abrasives and the object are contacted while they are rotated with respect to each other, to polish a surface of the object. By such lapping, it is formed a surface having a surface roughness smaller than that in the case of the grinding and larger than that in the case of micro lapping (polishing). It is preferably used abrasives composed of SiC. Al₂O₃, diamond, CBN or the like having a high hardness and having a grain size of about 0.5 μm to 15 μm.

Micro lapping (polishing) means that a polishing pad and an object are contacted with each other through free abrasives while they are rotated with each other, or fixed abrasives and the object are contacted with each other while they are rotated with each other, for subjecting a surface of the object to micro lapping to flatten it. By such polishing, it is possible to obtain a crystal growth surface having a surface roughness smaller than that in the case of the lapping.

(Treatment by Inductively Coupled Plasma)

Inductively coupled plasma (abbreviated as ICP) is to apply a high voltage on a gas to generate plasma and further to apply variable magnetic field of a high frequency, so that Joule heat is generated by eddy current in the plasma to obtain high temperature plasma.

Specifically, a coil is wound around a flow route composed of a tube of quartz glass or the like, through which a gas passed, and a large current of a high frequency is flown in the flow route to generate variable magnetic field of a high voltage and high frequency and to flow the gas in the flow route so that inductively coupled plasma is generated. The plasma is supplied onto the surface of the GaN substrate.

Here, the standardized direct current bias potential (Vdc/S) during the etching may preferably be made −10V/cm² or higher. Vdc means a direct current bias voltage (unit of V) applied between electrodes. “S” means a total area (unit of cm²) of the GaN surface to be treated. Vdc/S means a bias voltage during the etching, standardized by the total area of the GaN surface to be treated. According to the present invention, Vdc/S may be made −10V/cm² or higher. Although the bias voltage is changed by combination of gallium nitride composite substrates and setting method, in the case that Vdc/S is below this, the processing damage onto the uppermost surface of GaN becomes deeper. On the viewpoint, Vdc/S may preferably be −8V/cm² or higher.

Further, on the viewpoint of accelerating the processing of the surface of the GaN substrate, Vdc/S may preferably be made −0.005V/cm² or lower, more preferably be −0.05V/cm² or lower, and still further preferably be −1.5V/cm² or lower.

Further, the electric power of the bias potential during the etching (electric power standardized by the area of the electrode) may preferably be 0.003 W/cm² or higher and more preferably be 0.03 W/cm² or higher, on the viewpoint of generating the plasma stably. Further, the electric power of the bias potential during the etching (the electric power standardized by the area of the electrode) may preferably be 2.0 W/cm² or lower and more preferably be 1.5 W/cm² or lower, on the viewpoint of reducing the processing damage on the surface of the GaN substrate.

The fluorine-based gas may preferably be one or more compound selected from the group consisting of carbon fluoride, fluorohydrocarbon and sulfur fluoride.

According to a preferred embodiment, the fluorine-based gas is one or more compound selected from the group consisting of CF₄, CH₃F, C₄F₈ and SF₆.

According to a preferred embodiment, the pit amount on the surface after the dry etching is substantially same as the pit amount on the surface before the dry etching. The pit amount is measured as follows.

AFM (Atomic force Microscope) is used to perform the observation of the surface in a visual field of 10 μm and to count a number of recesses of 1 nm or larger with respect to the surrounding, so that it can be evaluated.

According to a preferred embodiment, the arithmetic surface roughness Ra of the surface of the substrate after the dry etching is substantially same as the arithmetic surface roughness Ra of the substrate surface before the dry etching. Besides, Ra is a measured value standardized by .JIS B 0601(1994)·JIS B 0031(1994).

(Functional Layer and Functional Device)

The functional layer as described above may be composed of a single layer or a plurality of layers. Further, as the functions, it may be used as a white LED with high brightness and improved color rendering index, a blue-violet laser disk for high-speed and high-density optical memory, a power device for an inverter for a hybrid car or the like.

As a semiconductor light emitting diode (LED) is produced on the GaN substrate by a vapor phase process, preferably by metal organic vapor phase deposition (MOCVD) method, the dislocation density inside of the LED can be made comparable with that of the GaN substrate.

The film-forming temperature of the functional layer may preferably be 950° C. or higher and more preferably be 1000° C. or higher, on the viewpoint of the film-formation rate. Further, on the viewpoint of preventing defects, the film-forming temperature of the functional layer may preferably be 1200° C. or lower and more preferably be 1150° C. or lower.

The material of the functional layer may preferably be a nitride of a group 13 element. Group 13 element means group 13 element according to the Periodic Table determined by IUPAC. The group 13 element is specifically gallium, aluminum, indium, thallium or the like. Further, as an additive, it may be listed carbon, a metal having a low melting point (tin, bismuth, silver, gold), and a metal having a high melting point (a transition metal such as iron, manganese, titanium, chromium). The metal having a low melting point may be added for preventing oxidation of sodium, and the metal having a high melting point may be incorporated from a container for containing a crucible, a heater of a growing furnace or the like.

The light emitting device structure includes, an n-type semiconductor layer, a light emitting region provided on the n-type semiconductor layer and a p-type semiconductor layer provided on the light emitting region, for example. According to the light emitting device 15 shown in FIG. 1(c), an n-type contact layer 5a, an n-type clad layer 5b, an activating layer 5c, a p-type clad layer 5d and a p-type contact layer 5e are formed on the GaN substrate 4 to constitute the light emitting structure 5.

Further, the light emitting structure described above may preferably further include an electrode for the n-type semiconductor layer, an electrode for the p-type semiconductor layer, a conductive adhesive layer, a buffer layer and a conductive supporting body or the like not shown.

According to the light emitting structure, as light is emitted in the light emitting region through re-combination of holes and electrons injected through the semiconductor layers, the light is drawn through the side of a translucent electrode on the p-type semiconductor layer or the film of the nitride single crystal of the group 13 element. Besides, the translucent electrode means an electrode capable of transmitting light and made of a metal thin film or transparent conductive film formed substantially over the whole of the p-type semiconductor layer.

### EXAMPLES

### Example 1

The GaN substrate was produced according to the following procedure.

Specifically, it was prepared a self-supporting type seed crystal substrate 1 made of gallium nitride seed crystal whose in-plane distribution of dislocation density by CL (cathode luminescence) was 2×10⁸/cm² in average excluding its outer periphery of 1 cm. The thickness of the seed crystal was 400 μm.

The gallium nitride layer 2 was formed by flux method using the seed crystal substrate 1. Specifically, Na and Ga were charged into a crucible, held at 870° C. and 4.0 MPa (nitrogen atmosphere) for 5 hours, and then cooled to 850° C. over 10 minutes. It was then held at 4.0 MPa for 20 hours to grow a gallium nitride layer 2. An alumina crucible was used, and the raw materials were Na:Ga=40 g:30 g. For agitating solution, the direction of rotation was changed to clockwise or anti-clockwise direction per every 600 minutes. The rotational rate was made 30 rpm.

After the reaction, it was cooled to room temperature and the flux was removed by chemical reaction with ethanol to obtain the gallium nitride layer 2 having a growth thickness of 100 μm.

The thus obtained substrate was fixed on a ceramic surface plate and then ground with abrasives of #2000 to make the surface flat. Then, the surface was smoothened by lapping using diamond abrasives. The sizes of the abrasives were lowered from 3 μm to 0.1 μm stepwise for improving the flatness. The arithmetic average roughness Ra of the surface of the substrate was 0.5 nm. The thickness of the gallium nitride layer after the polishing was 15 μm. Further, the substrate was colorless and transparent.

The thus polished surface state was measured by PL to prove that a luminescence peak having a small intensity ratio was observed. Further, as it was observed by CL, it was black without substantial luminescence and dark spots could not be observed. That is, it was proved that the stress by the processing was proved to be large (the thickness of the stressed region was thicker than the depth of penetration of electron beam).

Then, the surface of the GaN substrate was subjected to dry etching. For the dry etching, it was used an inductively coupled type plasma etching system. A fluorine-based gas (CF₄) was used as the etching gas to perform the dry etching. The size of electrodes was about 8 inches. The etching conditions were as follows.

Output power; (RF, 400 W, bias: 200 W)
Chamber pressure: 1 Pa
Etching time period; 10 minutes
Standardized direct current bias potential (Vdc/S): −5.2V/cm²
Electric power of bias voltage (electric power standardized by an area of the electrode): 1.3 W/cm².

As a result, the etching rate was 0.006 micron/minute and the etching depth was about 0.06 micron. The substrate remained to be colorless and transparent.

The surface of the substrate after the dry etching treatment was subjected to PL measurement to prove that luminescence peak having a high intensity ratio was observed. Further, as it was observed by CL, the ratio of the peak intensities of the CL spectra in the brighter region before and after the dry etching was proved to be more than 5, so that the dark spots corresponding to the defects could be clearly observed. Further, as elements on the surface were confirmed by XPS (X ray photoemission spectroscopy), spectrum corresponding to carbon was detected other than GaN. Spectra corresponding to fluorine, chlorine and silicon were not detected.

This substrate was used to produce an LED, it could be produced an LED having a high luminous efficiency. Further, leak current under a low driving voltage (for example, 2 to 2.5 V) was very low.

### Example 2

The GaN substrate was obtained similarly as the Example 1. However, the thickness of the seed crystal layer was made 3 μm, and the thickness of the grown GaN layer was made 80 μm. The thickness of the GaN layer after the polishing was made 15 μm

Thereafter, as the Example 1, it was subjected to dry etching. The etching conditions were as follows.

Output power; (RF, 400 W, bias: 200 W)
Chamber pressure: 1 Pa
Etching time period; 5 minutes
Standardized direct current bias potential (Vdc/S): −7.2V/cm²
Electric power of bias voltage (electric power standardized by an area of the electrode): 0.8 W/cm².

As a result, the etching rate was 0.005 μm/minute and the etching depth was about 0.025 μm. The substrate remained to be colorless and transparent. The surface of the substrate after the dry etching treatment was subjected to PL measurement to prove that luminescence peak having a high intensity ratio was observed. Further, as the substrate surface was observed by CL, the dark spots corresponding to the defects could be clearly observed. Further, as elements on the surface were confirmed by XPS, spectrum corresponding to carbon was detected other than GaN. Spectra corresponding to fluorine, chlorine and silicon were not detected. As this substrate was used to produce an LED, it could be produced an LED having a high luminous efficiency. Further, leak current under a low driving voltage (for example, 2 to 2.5 V) was very low.

### Example 3

The experiment was performed as the Example 1. However, the gas specie for the dry etching was changed to SF₆ and the etching conditions were made as follows.

Output power; (RF, 400 W, bias: 200 W)
Chamber pressure: 1 Pa
Etching time period; 5 minutes
Standardized direct current bias potential (Vdc/S): −3.6V/cm²
Electric power of bias voltage (electric power standardized by an area of the electrode): 1.4 W/cm².

As a result, the etching rate was 0.005 μm/minute and the etching depth was about 0.025 μm. The substrate remained to be colorless and transparent.

The surface of the substrate after the dry etching treatment was subjected to PL measurement to prove that luminescence peak having a high intensity ratio was observed. Further, as the substrate surface was observed by CL, the dark spots corresponding to the defects could be clearly observed. Further, as elements on the surface were confirmed by XPS, spectrum corresponding to carbon was detected other than GaN. Spectra corresponding to fluorine, chlorine and silicon were not detected.

As this substrate was used to produce an LED, it could be produced an LED having a high luminous efficiency. Further, leak current under a low driving voltage (for example, 2 to 2.5 V) was very low.

### Comparative Example 1

The experiment was performed as the Example 1. However, the gas specie for the dry etching was changed to chlorine-based gas (gas flow rate: BCl₃+Cl₂=3:1) and the etching conditions were made as follows.

Output power; (RF, 400 W, bias: 200 W)
Chamber pressure: 1 Pa
Etching time period; 5 minutes
Standardized direct current bias potential (Vdc/S): −13.1V/cm²
Electric power of bias voltage (electric power standardized by an area of the electrode): 1.3 W/cm².

As a result, the etching rate was 0.5 μm/minute and the etching depth was about 2.5 μm. The substrate remained to be colorless and transparent.

The surface of the substrate after the dry etching treatment was subjected to PL measurement to prove that luminescence peak having a high intensity ratio was observed. However, as the substrate was observed by CL, the ratio of the peak intensities of the CL spectra of the brighter region before and after the dry etching was proved to be less than 1.5. That is, although the images could be seen than those before the dry etching, the intensity ratio of luminescence spectra was still low to provide dark images, so that the dark spots could not be clearly observed. An additional processing of 5 minutes was performed and it was then observed by CL again, the luminescence image was not changed and the dark spots could not be observed. Further, as elements on the surface were confirmed by XPS, spectrum corresponding to chlorine was detected other than GaN. Spectra corresponding to fluorine and carbon were not detected.

As described above, by using a chlorine-based gas, damages due to the plasma were further generated on the surface of GaN and the processing stress could not be prevented.

As the substrate was used to produce an LED, leak current under a low driving voltage (for example, 2 to 2.5 V) was very large and the LED performances were not good. It is probably due to a chloride formed on the uppermost surface of GaN.

### Comparative Example 2

The experiment was performed as the Example 1. However, the dry etching system was changed from the inductively-coupled type to parallel plate type, and the etching conditions were made as follows.

Output power; 600 W
Chamber pressure: 3 Pa
Etching time period; 5 minutes
Standardized direct current bias voltage (Vdc/S): −11.3V/cm²

As a result, the etching rate was 0.02 μm/minute and the etching depth was about 0.1 μm. The substrate remained to be colorless and transparent.

The surface of the substrate after the dry etching treatment was subjected to PL measurement to prove that luminescence peak having a high intensity ratio was observed. However, as the substrate surface was observed by CL, although the images could be seen than those before the dry etching, the intensity ratio of luminescence spectra was still low to provide dark images, so that the dark spots could not be observed. An additional processing of 5 minutes was performed and it was then observed by CL, the intensity ratio was not changed and the dark spots could not be observed. Further, as elements on the surface were confirmed by XPS, spectrum corresponding to carbon was detected other than GaN. Spectra corresponding to fluorine, chlorine and silicon were not detected.

### Example 4

The experiment was performed as the Example 1. However, the etching conditions were made as follows.

Output power; (RF, 400 W, bias: 300 W)
Chamber pressure: 1 Pa
Etching time period; 3 minutes
Standardized direct current bias potential (Vdc/S): −9.2V/cm²
Electric power of bias voltage (electric power standardized by an area of the electrode): 1.9 W/cm².

As a result, the etching rate was 0.06 μm/minute and the etching depth was about 0.18 μm. The substrate remained to be colorless and transparent.

The surface of the substrate after the dry etching treatment was subjected to PL measurement to prove that luminescence peak having a high intensity ratio was observed. Further, as the substrate surface was observed by CL, the dark spots corresponding to the defects could be observed. Further, as elements on the surface were confirmed by XPS, spectrum corresponding to carbon was detected other than GaN. Spectra corresponding to fluorine, chlorine and silicon were not detected.

This substrate was used to produce an LED, the LED performance was good. Further, leak current under a low driving voltage (for example, 2 to 2.5 V) was small.

### Comparative Example 3

The experiment was performed as the Example 1, except that CMP finishing was performed instead of the dry etching.

The surface of the substrate after the CMP was subjected to PL measurement to prove that luminescence peak having a high intensity ratio was observed. Further, as it was observed by CL, the dark spots corresponding to the defects could be clearly observed. On the other hand, as the surface of the substrate was measured by AFM (Atomic Force Microscope), many etching pits were generated. Further, as elements on the surface were confirmed by XPS, spectrum corresponding to silicon was detected other than GaN. Spectra corresponding to fluorine, chlorine and carbon were not detected.

As this substrate was used to produce an LED, leak current under a low driving voltage (for example, 2 to 2.5 V) was very large and the performance as LED was poor. This is probably due to the etching pits generated on the substrate surface by CMP.

### Example 5

The experiment was performed as the Example 1. The etching conditions were made as follows.

Output power; (RF, 150 W, bias: 10 W)
Chamber pressure: 1 Pa
Etching time period; 30 minutes
Standardized direct current bias potential (Vdc/S): −1.7V/cm²
Electric power of bias voltage (electric power standardized by an area of the electrode): 0.05 W/cm².

As a result, the etching rate was 0.001 μm/minute and the etching depth was about 0.03 μm.

The surface of the substrate after the dry etching treatment was subjected to PL measurement to prove that luminescence peak having a high intensity ratio was observed. Further, as the substrate surface was observed by CL, the dark spots corresponding to the defects could be observed. Further, as elements on the surface were confirmed by XPS, spectrum corresponding to carbon was detected other than GaN. Spectra corresponding to fluorine, chlorine and silicon were not detected.

As this substrate was used to produce an LED, it could be produced an LED having a high luminous efficiency. Further, leak current under a low driving voltage (for example, 2 to 2.5 V) was very low.

### Example 6

The experiment was performed as the Example 1. The etching conditions were made as follows.

Output power; (RF, 50 W, bias: 10 W)
Chamber pressure: 1 Pa
Etching time period; 30 minutes
Standardized direct current bias potential (Vdc/S): −0.02V/cm²
Electric power of bias voltage (electric power standardized by an area of the electrode): 0.02 W/cm².

As a result, the etching rate was 0.001 μm/minute and the etching depth was about 0.03 μm. However, the plasma was unstable and deviation of etching distribution was observed.

The surface of the substrate after the dry etching treatment was subjected to PL measurement to prove that luminescence peak having a high intensity ratio was observed. Further, as the substrate surface was observed by CL, the dark spots corresponding to the defects could be observed. Further, as elements on the surface were confirmed by XPS, spectrum corresponding to carbon was detected other than GaN. Spectra corresponding to fluorine, chlorine and silicon were not detected.

As this substrate was used to produce an LED, it could be produced an LED having a high luminous efficiency. Further, leak current under a low driving voltage (for example, 2 to 2.5 V) was very low.

1. A method of producing a substrate comprising a surface gallium nitride layer, said method comprising:
using a plasma etching system comprising a plasma generating system of inductively coupled type; and
introducing a fluorine-based gas to perform a dry etching treatment of a surface of said gallium nitride layer.

2. The method of claim 1, wherein said fluorine-based gas comprises one or more kind of compound selected from the group consisting of carbon fluoride, fluorohydrocarbon and sulfur fluoride.

3. The method of claim 1, wherein said fluorine-based gas comprises one or more kind of compound selected from the group consisting of CF₄, CHF₃, C₄F₈ and SF₆.

4. The method of claim 1, wherein a standardized direct current bias potential of −10V/cm² or higher is applied in said dry etching treatment.

5. The method of claim 1, wherein said surface is subjected to mechanical polishing and then to said dry etching treatment without intervening chemical mechanical polishing.

6. The method of claim 1, wherein a pit amount on said surface after said dry etching treatment is substantially same as a pit amount on said surface before said dry etching treatment.

7. The method of claim 1, wherein an arithmetic average roughness Ra of said surface after said dry etching treatment is substantially same as an arithmetic average roughness Ra of said surface before said dry etching treatment.

8. The method of claim 1, further comprising the step of producing said gallium nitride layer by a flux method.

9. The method of claim 1, wherein said gallium nitride layer is formed on a supporting body.

10. The method of claim 1, wherein said substrate is in use for forming a functional layer on said surface of said gallium nitride layer, said functional layer comprising a nitride of a group 13 element.

11. The method of claim 10, wherein said functional layer comprises a semiconductor light emitting diode structure.

12. The method of claim 1, further comprising the step of forming a functional layer on said surface of said gallium nitride layer after said dry etching treatment, said functional layer comprising a nitride of a group 13 element.

13. The method of claim 12, wherein said functional layer comprises a semiconductor light emitting diode structure.

14. The method of claim 1, wherein said surface is subjected to mechanical polishing for thinning said gallium nitride layer and then to said dry etching treatment.

15. The method of claim 14, wherein said surface is subjected to said mechanical polishing and then to said dry etching treatment without intervening chemical mechanical polishing.

16. The method of claim 4, wherein a standardized direct current bias potential of −0.005V/cm² or lower is applied in said dry etching treatment.

17. The method of claim 4, wherein an electric power standardized by an area of an electrode during said dry etching treatment is 0.003 W/cm² or higher and 2.0 W/cm² or lower.”
